(19) United States
(12) Patent Application Publication
(10) Pub. No.: US 2026/0349335 A1
(43) Pub. Date: Nov. 5, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si, Gyeonggi-do (KR)

(72) Inventor: Young Keun KIM, Suwon-si (KR)

(21) Appl. No.: 19/571,705

(22) Filed: Mar. 19, 2026

(30) Foreign Application Priority Data
Apr. 16, 2025 (KR) 10-2025-0049734

(51) Int. Cl. G03F 7/004; C07F 7/22; G03F 7/00; G03F 7/20; H10P 50/00

(52) U.S. Cl. CPC G03F 7/0042; C07F 7/2224; G03F 7/2004; G03F 7/70033; H10P 50/71; H10P 50/73

(57) ABSTRACT

A semiconductor photoresist composition and a method of forming patterns using the semiconductor photoresist composition, the semiconductor photoresist composition including an organometallic compound represented by Chemical Formula 1 and a solvent,

Rₘ₁Sn(OR′)₄₋ₘ₁. [Chemical Formula 1]

### CROSS-REFERENCE TO RELATED APPLICATION

This application claims priority to and the benefit of Korean Patent Application No. 10-2025-0049734 filed with the Korean Intellectual Property Office on Apr. 16, 2025, the entire contents of which are incorporated herein by reference.

### BACKGROUND

### 1. Field

Embodiments relate to a semiconductor photoresist composition and a method of forming patterns using the same.

### 2. Description of the Related Art

EUV (extreme ultraviolet) lithography is paid attention to as one essential technology for manufacturing a next generation semiconductor device. The EUV lithography is a pattern-forming technology using an EUV ray having a wavelength of 13.5 nm as an exposure light source. According to the EUV lithography, an extremely fine pattern (e.g., less than or equal to 20 nm) may be formed in an exposure process during a manufacture of a semiconductor device.

### SUMMARY

Embodiments are directed to a semiconductor photoresist composition, including an organometallic compound represented by Chemical Formula 1 and a solvent:

Rₘ₁Sn(OR′)₄₋ₘ₁ [Chemical Formula 1]
wherein, in Chemical Formula 1, R is a photosensitive reactive group containing at least one unsaturated bond, R′ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, L^{a}-O—R^{a} (wherein L^{a} is a single bond or a substituted or unsubstituted C1 to C20 alkylene group and R^{a} is a substituted or unsubstituted C1 to C20 alkyl group, a substituted or unsubstituted C6 to C30 aryl group, or a substituted or unsubstituted C7 to C30 arylalkyl group), and m1 is an integer of 1 to 3.

A method of forming patterns, the method including forming an etching-objective layer on a substrate, coating the semiconductor photoresist composition according to some embodiments on the etching-objective layer to form a photoresist film, patterning the photoresist film to form a photoresist pattern, and etching.

### BRIEF DESCRIPTION OF THE DRAWINGS

Features will become apparent to those of skill in the art by describing in detail exemplary embodiments with reference to the attached drawings in which:

FIGS. 1A-1E are cross-sectional views illustrating stages in a method of forming patterns using a semiconductor photoresist composition according to some example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In the following description of the present embodiments, the well-known functions or constructions will not be described in order to clarify the present embodiments. Also, the size and thickness of each configuration shown in the drawing are arbitrarily shown for better understanding and ease of description. In the drawings, the thickness of layers, films, panels, regions, etc., are enlarged for clarity. In the drawings, the thickness of a part of layers or regions, etc., is exaggerated for convenience of explanation.

As used herein, “substituted” refers to replacement of a hydrogen atom by deuterium, a halogen, a hydroxy group, a thiol group, a cyano group, a nitro group, a carbonyl group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, when a definition is not otherwise provided, “alkyl group” refers to a linear or branched aliphatic hydrocarbon group. The alkyl group may be “saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, when a definition is not otherwise provided, “cycloalkyl group” refers to a monovalent cyclic aliphatic hydrocarbon group.

The cycloalkyl group may be a C3 to C10 cycloalkyl group, e.g., a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group.

As used herein, “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms) functional group.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

In the chemical formulae described herein, t-Bu refers to a tert-butyl group.

Hereinafter, a semiconductor photoresist composition according to some example embodiments is described.

A semiconductor photoresist composition according to some example embodiments includes an organometallic compound represented by Chemical Formula 1 and a solvent.

Rₘ₁Sn(OR′)₄₋ₘ₁ [Chemical Formula 1]

In Chemical Formula 1, R may be or include, e.g., a photosensitive reactive group containing at least one unsaturated bond.

R′ may be or include, e.g., a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or L^{a}-O—R^{a} (wherein L^{a} may be, e.g., a single bond or a substituted or unsubstituted C1 to C20 alkylene group and R^{a} may be, e.g., a substituted or unsubstituted C1 to C20 alkyl group, a substituted or unsubstituted C6 to C30 aryl group, or a substituted or unsubstituted C7 to C30 arylalkyl group).
m1 may be, e.g., an integer of 1 to 3.

The present embodiments may help improve sensitivity by introducing a functional group capable of stabilizing radical compounds generated during exposure, and maximize a difference in solubility between exposed and unexposed regions of a photoresist film in a developer solution, thereby increasing pattern formation ability and process margin.

The functional group capable of stabilizing the radical compound is may be, e.g., an unsaturated bond included in R of Chemical Formula 1, and R may include, e.g., a substituted or unsubstituted C2 to C20 alkenyl group, a substituted or unsubstituted C6 to C30 aryl group, C(O)—R^{c} (wherein R^{c} may be, e.g., hydrogen, a substituted or unsubstituted C1 to C20 alkyl group, or a substituted or unsubstituted C6 to C30 aryl group), P(O)OR^{d}R^{e} (wherein R^{d} and R^{e} may each independently be, e.g., a substituted or unsubstituted C1 to C20 alkyl group or a substituted or unsubstituted C6 to C30 aryl group), P(O)OR^{f}OR^{g} (wherein R^{f} and R^{g} may each independently be, e.g., a substituted or unsubstituted C1 to C20 alkyl group or a substituted or unsubstituted C6 to C30 aryl group), S(O)R^{h} (wherein R^{h} may be, e.g., a substituted or unsubstituted C1 to C20 alkyl group or a substituted or unsubstituted C6 to C30 aryl group), or S(O)₂Rⁱ (wherein Rⁱ may be, e.g., a substituted or unsubstituted C1 to C20 alkyl group or a substituted or unsubstituted C6 to C30 aryl group) or a group may be linked to a substituent adjacent to R to form, e.g., a C3 to C30 saturated alicyclic hydrocarbon group substituted with an unsaturated group, a substituted or unsubstituted C3 to C30 unsaturated alicyclic hydrocarbon group, or a substituted or unsubstituted C6 to C30 aromatic hydrocarbon group.

The unsaturated group refers to a substituent containing an unsaturated bond, and may be, e.g., a substituted or unsubstituted C2 to C20 alkenyl group, a substituted or unsubstituted C6 to C30 aryl group, ═O, ═S, —C(O)—R^{c} (wherein R^{c} may be, e.g., hydrogen, a substituted or unsubstituted C1 to C20 alkyl group, or a substituted or unsubstituted C6 to C30 aryl group), —P(O)OR^{d}R^{e} (wherein R^{d} and R^{e} may each independently be, e.g., a substituted or unsubstituted C1 to C20 alkyl group or a substituted or unsubstituted C6 to C30 aryl group), —P(O)OR^{f}OR^{g} (wherein R^{f} and R^{g} may each independently be, e.g., a substituted or unsubstituted C1 to C20 alkyl group or a substituted or unsubstituted C6 to C30 aryl group), —S(O)R^{h} (wherein R^{h} may be, e.g., a substituted or unsubstituted C1 to C20 alkyl group or a substituted or unsubstituted C6 to C30 aryl group), or —S(O)₂Rⁱ (wherein Rⁱ is a substituted or unsubstituted C1 to C20 alkyl group or a substituted or unsubstituted C6 to C30 aryl group).

In an implementation, Chemical Formula 1 may be represented by Chemical Formula 1-1.

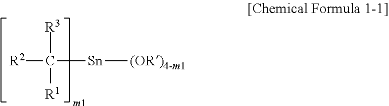

In Chemical Formula 1-1, each R′ may independently be or include, e.g., a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or L^{a}-O—R^{a} (wherein L^{a} may be, e.g., a single bond, or a substituted or unsubstituted C1 to C20 alkylene group and R^{a} may be, e.g., a substituted or unsubstituted C1 to C20 alkyl group, a substituted or unsubstituted C6 to C30 aryl group, or a substituted or unsubstituted C7 to C30 arylalkyl group).

R¹ to R³ may each independently be or include, e.g., hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, C(O)—R^{c} (wherein R^{c} may be, e.g., a substituted or unsubstituted C1 to C20 alkyl group or a substituted or unsubstituted C6 to C30 aryl group), P(O)OR^{d}R^{e} (wherein R^{d} and R^{e} may each independently be, e.g., a substituted or unsubstituted C1 to C20 alkyl group or a substituted or unsubstituted C6 to C30 aryl group), P(O)OR^{f}OR^{g} (wherein R^{f} and R^{g} may each independently be, e.g., a substituted or unsubstituted C1 to C20 alkyl group or a substituted or unsubstituted C6 to C30 aryl group), S(O)R^{h} (wherein R^{h} may be, e.g., a substituted or unsubstituted C1 to C20 alkyl group or a substituted or unsubstituted C6 to C30 aryl group), or S(O)₂Rⁱ (wherein Rⁱ may be, e.g., a substituted or unsubstituted C1 to C20 alkyl group or a substituted or unsubstituted C6 to C30 aryl group).

At least one of R¹ to R³ may be, e.g., a substituted or unsubstituted C2 to C20 alkenyl group, a substituted or unsubstituted C6 to C30 aryl group, C(O)—R^{c} (wherein R^{c} may be, e.g., hydrogen, a substituted or unsubstituted C1 to C20 alkyl group, or a substituted or unsubstituted C6 to C30 aryl group), P(O)OR^{d}R^{e} (wherein R^{d} and R^{e} may each independently be, e.g., a substituted or unsubstituted C1 to C20 alkyl group or a substituted or unsubstituted C6 to C30 aryl group), P(O)OR^{f}OR^{g} (wherein R^{f} and R^{g} may each independently be, e.g., a substituted or unsubstituted C1 to C20 alkyl group or a substituted or unsubstituted C6 to C30 aryl group), S(O)R^{h} (wherein R^{h} may be, e.g., a substituted or unsubstituted C1 to C20 alkyl group or a substituted or unsubstituted C6 to C30 aryl group), or S(O)₂Rⁱ (wherein Rⁱ may be, e.g., a substituted or unsubstituted C1 to C20 alkyl group or a substituted or unsubstituted C6 to C30 aryl group).

Adjacent groups among R¹ to R³ may be linked to form a C3 to C30 saturated alicyclic hydrocarbon group substituted with an unsaturated group, a substituted or unsubstituted C3 to C30 unsaturated alicyclic hydrocarbon group, or a substituted or unsubstituted C6 to C30 aromatic hydrocarbon group.
m1 may be, e.g., an integer of 1 to 3.

In an implementation, when at least one of R¹ to R³ contains a C(O)—R^{c} group, a reaction such as the one depicted in Reaction Scheme 1 may occur. In particular, the radical generated after exposure may be stabilized by the carbonyl group and become more sensitive to the photosensitivity reaction, and accordingly, the difference in the properties of the exposed and unexposed regions may be maximized, which may help implement the excellent contrast performance.

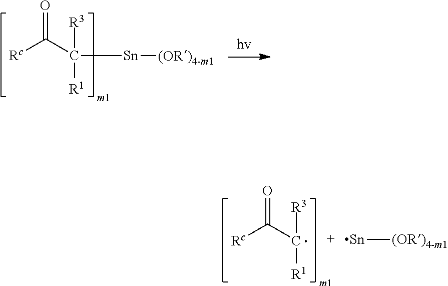

The organotin compound according to the present embodiments may simultaneously include a photosensitive reactive group and a hydrolyzable group as well as a functional group capable of stabilizing a radical compound on tin as a central metal.

In an implementation, at least one of R¹ to R³ may be a substituted or unsubstituted C2 to C10 alkenyl group, a substituted or unsubstituted C6 to C20 aryl group, C(O)—R^{c} (wherein R^{c} may be, e.g., hydrogen, a substituted or unsubstituted C1 to C10 alkyl group, or a substituted or unsubstituted C6 to C20 aryl group), P(O)OR^{d}R^{e} (wherein R^{d} and R^{e} may each independently be, e.g., a substituted or unsubstituted C1 to C10 alkyl group or a substituted or unsubstituted C6 to C20 aryl group), P(O)OR^{f}OR^{g} (wherein R^{f} and R^{g} may each independently be, e.g., a substituted or unsubstituted C1 to C10 alkyl group or a substituted or unsubstituted C6 to C20 aryl group), S(O)R^{h} (wherein R^{h} may be, e.g., a substituted or unsubstituted C1 to C10 alkyl group or a substituted or unsubstituted C6 to C20 aryl group), or S(O)₂Rⁱ (wherein Rⁱ may be, e.g., a substituted or unsubstituted C1 to C10 alkyl group or a substituted or unsubstituted C6 to C20 aryl group).

Adjacent groups among R¹ to R³ may be linked to form, e.g., a cyclopentyl group substituted with an unsaturated group, a cyclohexyl group substituted with an unsaturated group, a cycloheptyl group substituted with an unsaturated group, a cyclooctyl group substituted with an unsaturated group, a cyclononyl group substituted with an unsaturated group, or a cyclodecyl group substituted with an unsaturated group.

In an implementation, at least one of R¹ to R³ may be, e.g., a substituted or unsubstituted phenyl group, a substituted or unsubstituted tolyl group, a substituted or unsubstituted xylene group, C(O)—R^{c} (wherein R^{c} may be, e.g., hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), C(R^{r})═C(R^{s})(R^{t}) (wherein R^{r}, R^{s}, and R^{t} may each independently be, e.g., hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), P(O)OR^{d}R^{e} (wherein R^{d} and R^{e} may each independently be, e.g., a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), P(O)OR^{f}OR^{g} (wherein R^{f} and R^{g} may each independently be, e.g., a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), S(O)R^{h} (wherein R^{h} may be, e.g., a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), or S(O)₂Rⁱ (wherein Rⁱ may be, e.g., a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group).

Adjacent groups among R¹ to R³ may be linked to form, e.g., a cyclopentyl group substituted with an unsaturated group, a cyclohexyl group substituted with an unsaturated group, a cycloheptyl group substituted with an unsaturated group, a cyclooctyl group substituted with an unsaturated group, a cyclononyl group substituted with an unsaturated group, or a cyclodecyl group substituted with an unsaturated group.

In an implementation, at least one of R¹ to R³ may be, e.g., a substituent of Group 1-1 or adjacent groups among R¹ to R³ may be linked to form, e.g., a ring group of one of Group 1-2.

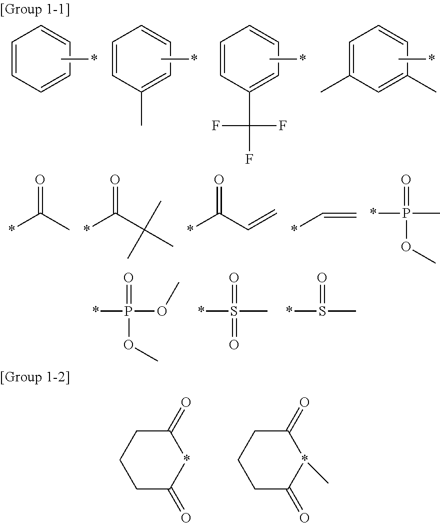

In Groups 1-1 and 1-2, * represents carbon to which R¹ to R³ are linked.

In an implementation, R′ may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or L^{a}-O—R^{a} (wherein L^{a} may be, e.g., a single bond or a substituted or unsubstituted C1 to C10 alkylene group and R^{a} may be, e.g., a substituted or unsubstituted C1 to C10 alkyl group, a substituted or unsubstituted C6 to C20 aryl group, or a substituted or unsubstituted C7 to C20 arylalkyl group).

In an implementation, R′ may be, e.g., a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, a substituted or unsubstituted methoxy group, a substituted or unsubstituted ethoxy group, a substituted or unsubstituted propoxy group, L^{a}-O—R^{a}(wherein L^{a} may be, e.g., a single bond, a substituted or unsubstituted methylene group, a substituted or unsubstituted ethylene group, a substituted or unsubstituted propylene group and R^{a} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted phenyl group, a substituted or unsubstituted tolyl group, a substituted or unsubstituted xylene group, or a substituted or unsubstituted benzyl group), or a combination thereof.

The organometallic compound may be, e.g., a compound of Group 2.

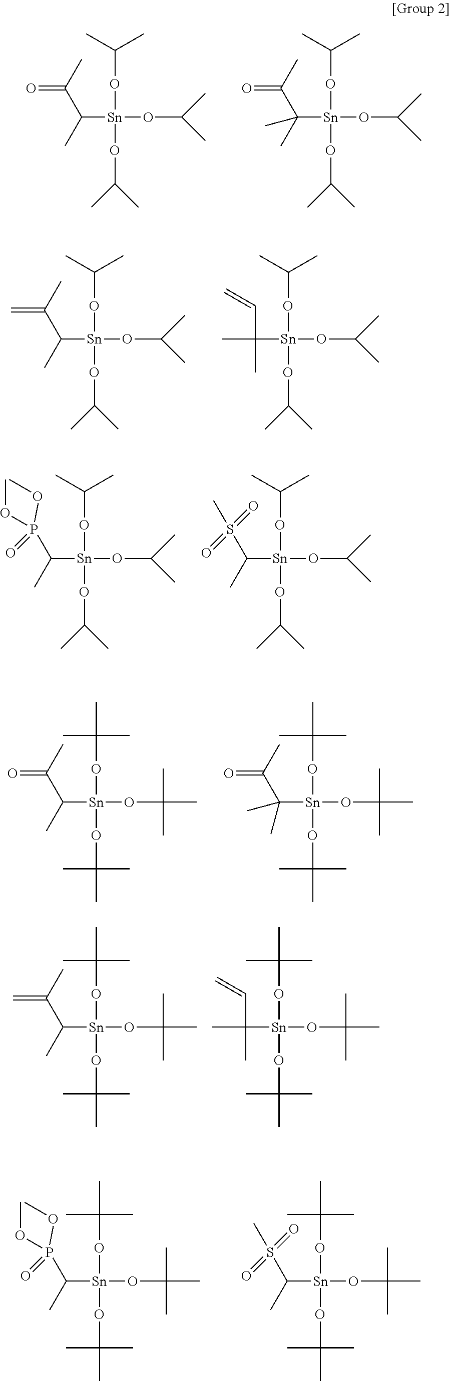

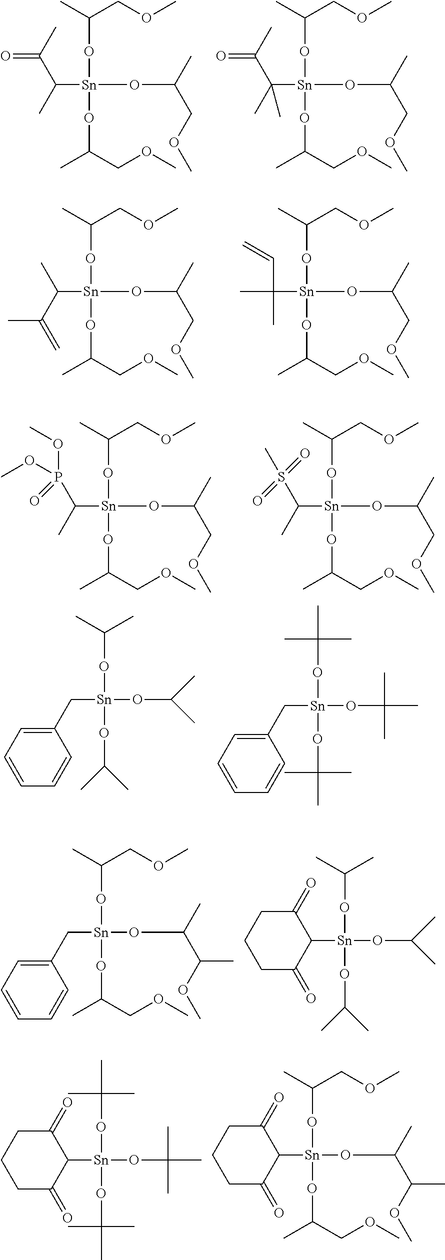

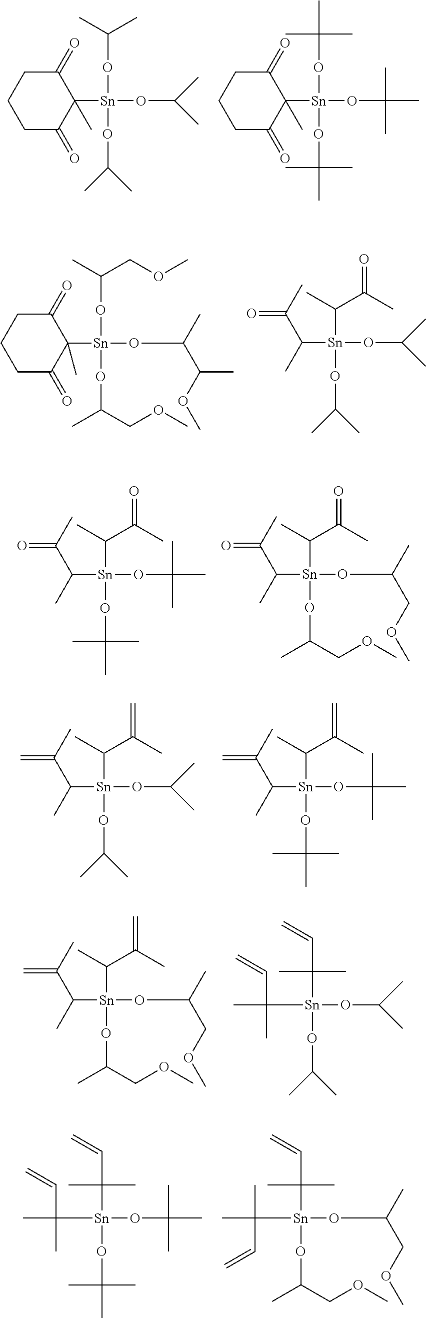

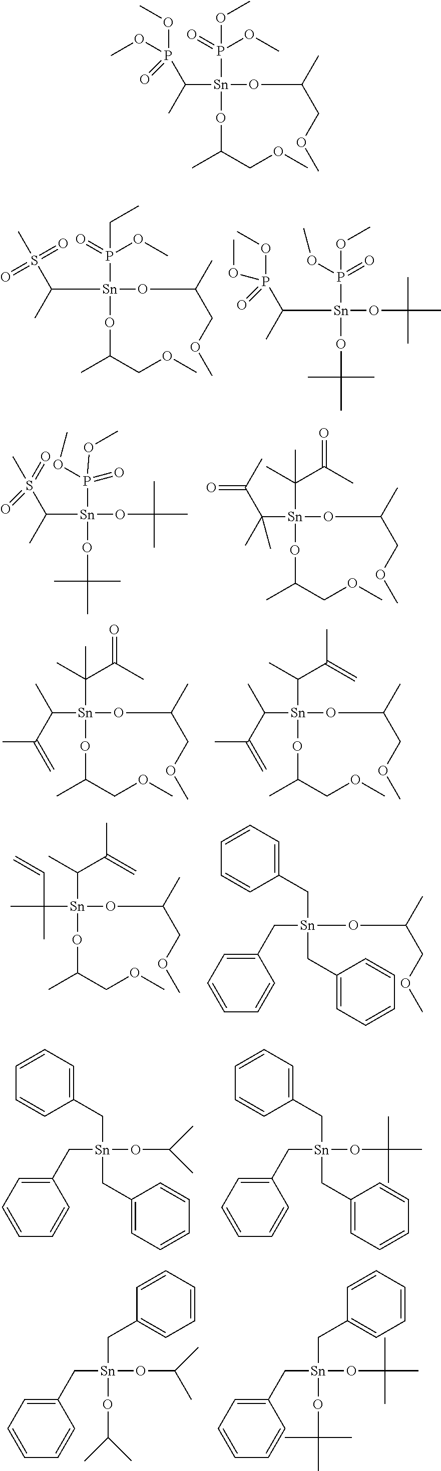

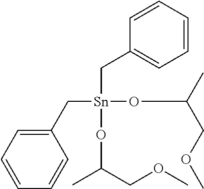 [SMILES: COCC(C)[O][Sn]([CH2]c1ccccc1)([CH2]c1ccccc1)[O]C(C)COC]

Such an organometallic compound may have excellent sensitivity due to its high reactivity to extreme ultraviolet light or additional secondary electrons generated thereby at about 13.5 nm.

In the semiconductor photoresist composition according to some example embodiments, the organometallic compound may be included in an amount of about 1 wt % to about 30 wt %, e.g., about 1 wt % to about 25 wt %, about 1 wt % to about 20 wt %, about 1 wt % to about 15 wt %, about 1 wt % to about 10 wt %, about 1 wt % to about 5 wt %, based on a total weight of the semiconductor photoresist composition. When the organometallic compound is included in the amount within the above range, the storage stability and etch resistance of the semiconductor photoresist composition are improved, and the resolution characteristics are improved.

The semiconductor photoresist composition according to some example embodiments may provide a semiconductor photoresist composition having excellent contrast characteristics by including the aforementioned organometallic compound.

The solvent included in the semiconductor photoresist composition according to some example embodiments may be an organic solvent, and may be, e.g., an aromatic compound (e.g., xylene or toluene), an alcohol (e.g., 4-methyl-2-pentenol, 4-methyl-2-propanol, 1-butanol, methanol, or isopropyl alcohol, 1-propanol), an ether (e.g., anisole or tetrahydrofuran), an ester (e.g., n-butyl acetate, propylene glycol monomethyl ether acetate, ethyl acetate, or ethyl lactate), a ketone (e.g., methyl ethyl ketone or 2-heptanone), or a mixture thereof.

In an implementation, the organic solvent may be an alcohol.

In an implementation, the semiconductor photoresist composition may further include a resin in addition to the aforementioned organometallic compound and solvent.

The resin may be a phenol-based resin including, e.g., an aromatic moiety of Group 3.

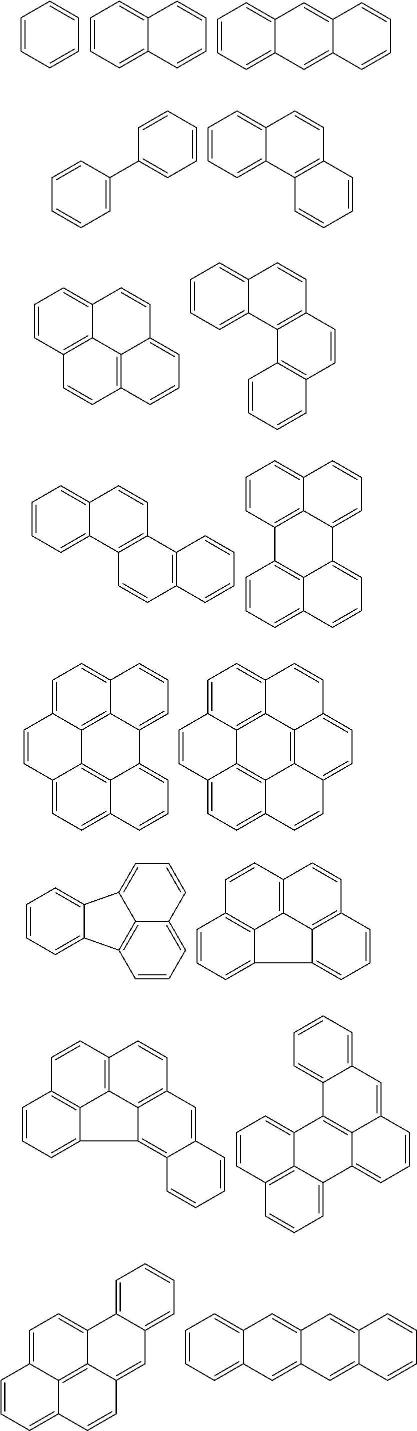

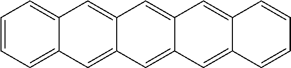 [SMILES: c1ccc2cc3cc4cc5ccccc5cc4cc3cc2c1]

The resin may have a weight average molecular weight of, e.g., about 500 to about 20,000.

The resin may be included in an amount of, e.g., about 0.1 wt % to about 50 wt %, based on the total weight of the semiconductor photoresist composition.

If the resin is included in the above weight range, it may have excellent etch resistance and heat resistance.

In an implementation, the semiconductor photoresist composition according to some example embodiments may be composed of the aforementioned organometallic compound, solvent, and resin. In an implementation, the semiconductor photoresist composition according to the aforementioned embodiment may further include an additive as needed. Examples of the additives may be a surfactant, a crosslinking agent, a leveling agent, an organic acid, a quencher, or a combination thereof.

The surfactant may include, e.g., an alkyl benzene sulfonate salt, an alkyl pyridinium salt, polyethylene glycol, a quaternary ammonium salt, or a combination thereof.

The crosslinking agent may be, e.g., a melamine-based crosslinking agent, a substituted urea-based crosslinking agent, an acryl-based crosslinking agent, an epoxy-based crosslinking agent, or a polymer-based crosslinking agent. It may be a crosslinking agent having at least two crosslinking forming substituents, e.g., a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, or the like.

The leveling agent may be used for improving coating flatness during printing and may be a commercially available leveling agent.

The organic acid may include, e.g., p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof.

The quencher may be, e.g., diphenyl (p-tolyl) amine, methyl diphenyl amine, triphenyl amine, phenylenediamine, naphthylamine, diaminonaphthalene, or a combination thereof.

The amount of the additives used may be controlled depending on desired properties.

In an implementation, the semiconductor photoresist composition may further include, e.g., a silane coupling agent as an adherence enhancer in order to improve a close-contacting force with the substrate (e.g., in order to improve adherence of the semiconductor photoresist composition to the substrate). The silane coupling agent may be, e.g., a silane compound including a carbon-carbon unsaturated bond such as vinyltrimethoxysilane, vinyl triethoxysilane, vinyl trichlorosilane, vinyl tris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane, trimethoxy[3-(phenylamino)propyl]silane, or the like.

The semiconductor photoresist composition may be formed into a pattern having a high aspect ratio without a collapse. Accordingly, in order to form a fine pattern having a width of about 5 nm to about 100 nm, e.g., about 5 nm to about 80 nm, about 5 nm to about 70 nm, about 5 nm to about 50 nm, about 5 nm to about 40 nm, about 5 nm to about 30 nm, about 5 nm to about 20 nm, or about 5 nm to about 10 nm, the semiconductor photoresist composition may be used for a photoresist process using light in a wavelength ranging from about 5 nm to about 150 nm, e.g., about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some example embodiments may be used to realize extreme ultraviolet lithography using an EUV light source of a wavelength of about 13.5 nm.

According to some example embodiments, a method of forming patterns using the aforementioned semiconductor photoresist composition is provided. In an implementation, the manufactured pattern may be a photoresist pattern.

The method of forming patterns according to some example embodiments includes forming an etching-objective layer on a substrate, coating the semiconductor photoresist composition on the etching-objective layer to form a photoresist film, patterning the photoresist film to form a photoresist pattern, and etching the etching-objective layer using the photoresist pattern as an etching mask.

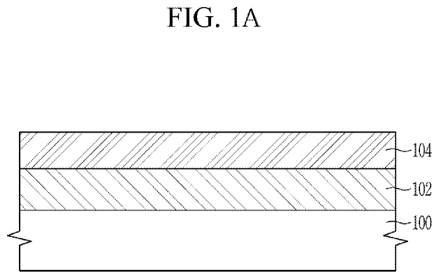

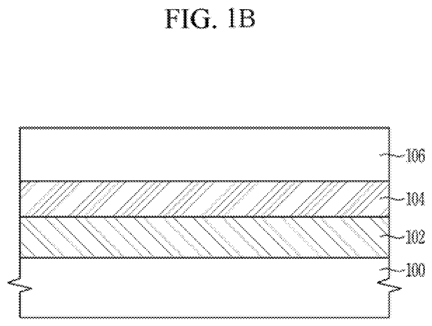

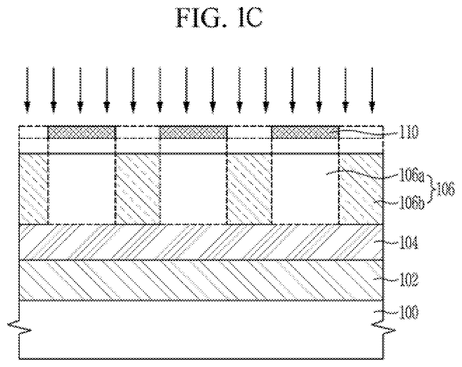

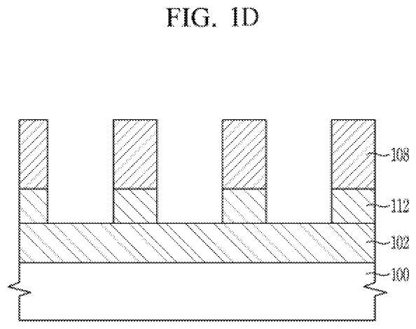

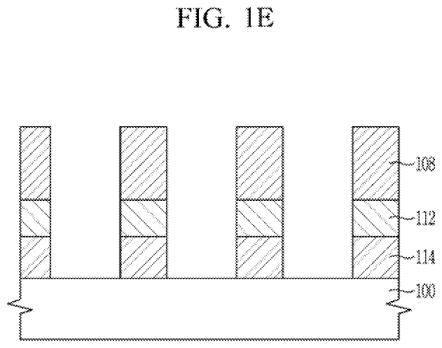

Hereinafter, a method of forming patterns using the semiconductor photoresist composition is described with reference to FIGS. 1A-1E. FIGS. 1A-1E which are cross-sectional views illustrating stages in a method of forming patterns using a semiconductor photoresist composition according to some example embodiments.

Referring to FIG. 1A, an object for etching is prepared. The object for etching may be a thin film 102 formed on a substrate 100. Hereinafter, the term “object for etching” indicates the thin film 102. A surface of the thin film 102 may be washed to remove impurities and the like thereon. The thin film 102 may be, e.g., a silicon nitride layer, a polysilicon layer, or a silicon oxide layer.

In an implementation, the resist underlayer composition for forming a resist underlayer 104 may be spin-coated on the surface of the washed thin film 102. In an implementation, suitable coating methods, e.g., spray coating, dip coating, knife edge coating, suitably printing methods, e.g., inkjet printing or screen printing, or the like may be used.

The coating process of the resist underlayer may be omitted, and hereinafter, a process including a coating of the resist underlayer is described.

In an implementation, the coated composition may be dried and baked to form a resist underlayer 104 on the thin film 102. The baking may be performed at about 100 °C to about 500 °C, e.g., at about 100 °C to about 300 °C.

Referring to FIG. 1B, the resist underlayer 104 may be formed between the substrate 100 and a photoresist film 106 and thus may prevent non-uniformity and pattern formability of a photoresist line width when a ray reflected from on the interface between the substrate 100 and the photoresist film 106 or a hardmask between layers is scattered into an unintended photoresist region.

The photoresist film 106 may be formed by coating the semiconductor photoresist composition on the resist underlayer 104. The photoresist film 106 may be obtained by coating the aforementioned semiconductor photoresist composition on the thin film 102 formed on the substrate 100 and then, curing it through a heat treatment.

In an implementation, the formation of a pattern by using the semiconductor photoresist composition may include coating the semiconductor resist composition on the substrate 100 having the thin film 102 through spin coating, slit coating, inkjet printing, or the like and then, drying it to form the photoresist film 106.

The semiconductor photoresist composition has already been described in detail above and will not be described again.

Subsequently, a substrate 100 having the photoresist film 106 may be subjected to a first baking process. The first baking process may be performed at, e.g., about 80 °C to about 120 °C.

Referring to FIG. 1C, the photoresist film 106 may be selectively exposed using a patterned mask 110.

In an implementation, the exposure may use as an activation radiation having a high energy, e.g., EUV light, (extreme ultraviolet light; a wavelength of about 13.5 nm), an E-Beam (an electron beam), or the like. In an implementation, the exposure may use as an activation radiation having short wavelengths, e.g., an i-line (a wavelength of about 365 nm), a KrF excimer laser (a wavelength of about 248 nm), an ArF excimer laser (a wavelength of about 193 nm), or the like.

In an implementation, the activation radiation for the exposure according to some example embodiments may be, e.g., radiation having a short wavelength ranging from about 5 nm to about 150 nm and having a high energy wavelength, e.g., in the form of EUV light (extreme ultraviolet light; a wavelength of 13.5 nm), an E-Beam (an electron beam), or the like.

The exposed region 106b of the photoresist film 106 may have a different solubility from the unexposed region 106a of the photoresist film 106 due to the formation of a polymer by a crosslinking reaction, e.g., a condensation reaction, between organometallic compounds.

In an implementation, the substrate 100 may be subjected to a second baking process. The second baking process may be performed at a temperature of, e.g., about 90 °C to about 200 °C. The exposed region 106b of the photoresist film 106 may become not easily dissoluble with respect to developers due to the second baking process.

In FIG. 1D, the unexposed region 106a of the photoresist film is dissolved and removed using the developer to form a photoresist pattern 108. Specifically, the unexposed region 106a of the photoresist film may be dissolved and removed by using an organic solvent such as 2-heptanone or the like to complete the photoresist pattern 108 corresponding to the negative tone image.

As described above, a developer used in a method of forming patterns according to some example embodiments may be an organic solvent. The organic solvent used in the method of forming patterns according to some example embodiments may be, e.g., a ketone, e.g., methylethylketone, acetone, cyclohexanone, 2-heptanone, or the like, an alcohol, e.g., 4-methyl-2-propanol, 1-butanol, isopropanol, 1-propanol, methanol, or the like, an ester, e.g., propylene glycol monomethyl ether acetate, ethyl acetate, ethyl lactate, n-butyl acetate, butyrolactone, or the like, an aromatic compound, e.g., benzene, xylene, toluene, or the like, or a combination thereof.

However, the photoresist pattern according to some example embodiments is not necessarily limited to the negative tone image but may be formed to have a positive tone image. Here, a developer used for forming the positive tone image may be a quaternary ammonium hydroxide composition, e.g., tetraethylammonium hydroxide, tetrapropylammonium hydroxide, tetrabutylammonium hydroxide, or a combination thereof.

As described above, exposure to radiation having a high energy, e.g., in the form of EUV light (extreme ultraviolet light; a wavelength of 13.5 nm), an E-Beam (an electron beam), or the like, or exposure to light having a wavelength such as i-line (wavelength of about 365 nm), KrF excimer laser (wavelength of about 248 nm), ArF excimer laser (wavelength of about 193 nm), or the like, may help provide a photoresist pattern 108 having a width of a thickness of about 5 nm to about 100 nm. In an implementation, the photoresist pattern 108 may have a width of a thickness of about 5 nm to about 90 nm, e.g., about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In an implementation, the photoresist pattern 108 may have a pitch having a half-pitch of less than or equal to about 50 nm, e.g., less than or equal to about 40 nm, less than or equal to about 30 nm, less than or equal to about 20 nm, or less than or equal to about 10 nm, and a line width roughness of less than or equal to about 5 nm, e.g., less than or equal to about 3 nm, less than or equal to about 2 nm, or less than or equal to about 1 nm.

In an implementation, the photoresist pattern 108 may be used as an etching mask to etch the resist underlayer 104. Through this etching process, an organic film pattern 112 may be formed. The organic film pattern 112 also may have a width corresponding to that of the photoresist pattern 108.

Referring to FIG. 1E, the exposed thin film 102 may be etched by applying the photoresist pattern 108 as an etching mask. In an implementation, the thin film is formed as a thin film pattern 114.

The etching of the thin film 102 may be performed by dry etching using, e.g., an etching gas, and the etching gas may be, e.g., CHF₃, CF₄, Cl₂, BCl₃, or a mixed gas thereof.

In the exposure process, the thin film pattern 114 formed by using the photoresist pattern 108 formed through the exposure process performed by using an EUV light source may have a width corresponding to that of the photoresist pattern 108. In an implementation, the thin film pattern 114 may have a width of about 5 nm to about 100 nm which may be equal to that of the photoresist pattern 108. In an implementation, the thin film pattern 114 formed by using the photoresist pattern 108 formed through the exposure process performed by using an EUV light source may have a width of about 5 nm to about 90 nm, e.g., about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm. In an implementation, the thin film pattern may have a width of less than or equal to about 20 nm, like that of the photoresist pattern 108.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Organometallic Compounds

### Synthesis Example 1: Synthesis of Compound Represented by Chemical Formula 2

In a 250 mL two-necked round-bottom flask, Ph₃SnCl (20 g, 51.9 mmol) was dissolved in 100 mL of anhydrous tetrahydrofuran (THF) and then, cooled to 0 °C in an ice bath, and a 1 M benzyl magnesium chloride THF solution (62.3 mmol) was slowly added thereto in a dropwise fashion. When the dropwise addition was completed, the mixture was stirred at room temperature (25 °C) for 12 hours. After distillation under a reduced pressure, 20 mL (236 mmol) of concentrated hydrochloric acid was slowly added thereto in a dropwise fashion and then, stirred at 80 °C for 12 hours. Subsequently, after decreasing the temperature to room temperature, HCl remaining there was removed therefrom. Then, 100 mL of diethyl ether was added thereto to dissolve the reaction mixture and then, cooled to −20 °C Then, sodium isopropoxide (180 mmol) was added thereto in a dropwise fashion and then, stirred at room temperature for 10 hours. The reaction mixture was vacuum-distilled, obtaining a compound represented by Chemical Formula 2.

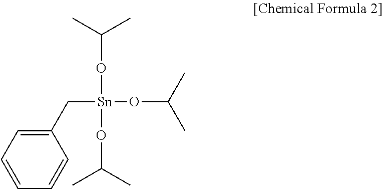 [SMILES: CC(C)[O][Sn]([CH2]c1ccccc1)([O]C(C)C)[O]C(C)C]

### Synthesis Example 2: Synthesis of Compound Represented by Chemical Formula 3

A compound represented by Chemical Formula 3 was obtained in the same manner as in Synthesis Example 1 except that 2-(3-methyl-2-butenyl) magnesium chloride was used instead of the 1 M benzyl magnesium chloride THF solution and sodium 1-methoxy-2-propoxide instead of the sodium isopropoxide were used.

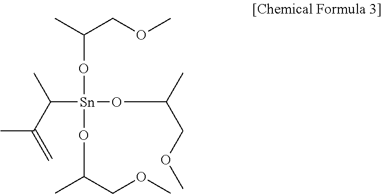 [SMILES: C=C(C)[CH](C)[Sn]([O]C(C)COC)([O]C(C)COC)[O]C(C)COC]

### Synthesis Example 3: Synthesis of Compound Represented by Chemical Formula 4

In a 250 mL two-necked round-bottom flask, Ph₃SnCl (20 g, 51.9 mmol) was dissolved in 100 mL of anhydrous tetrahydrofuran (THF) and then, cooled to 0 °C in an ice bath, and a 1 M benzyl magnesium chloride THF solution (62.3 mmol) was slowly added thereto in a dropwise fashion. After completing the dropwise addition, the mixture was stirred at room temperature (25 °C) for 12 hours. After distillation under a reduced pressure, 50 mL of acetic acid was slowly added thereto in a dropwise fashion and then, refluxed by heating at 80 °C for 12 hours. Subsequently, after decreasing the temperature to room temperature, the acetic acid was vacuum-distilled, obtaining a compound represented by Chemical Formula 4.

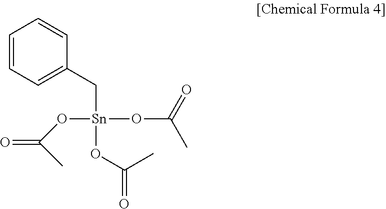 [SMILES: CC(=O)[O][Sn]([CH2]c1ccccc1)([O]C(C)=O)[O]C(C)=O]

### Synthesis Example 4: Synthesis of Compound Represented by Chemical Formula 5

A compound represented by Chemical Formula 5 was obtained in the same manner as in Synthesis Example 1 except that 2-(3-methyl-3-butenyl) magnesium chloride instead of the 1 M benzyl magnesium chloride THF solution and a mixture of 2-oxo-3-penten-4-ol sodium salt (34.6 mmol) and lithium tert-butoxide (17.3 mmol) instead of the sodium isopropoxide were used.

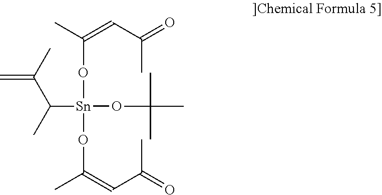 [SMILES: C=C(C)[CH](C)[Sn]([O]/C(C)=C\C(C)=O)([O]/C(C)=C\C(C)=O)[O]C(C)(C)C]

### Synthesis Example 5: Synthesis of Compound Represented by Chemical Formula 6

A compound represented by Chemical Formula 6 was obtained in the same manner as in Synthesis Example 1 except that lithium tert-butoxide instead of the 1 M benzyl magnesium chloride THF solution and sodium 1-methoxy-2-propoxide instead of the sodium isopropoxide were used.

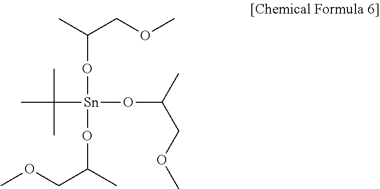

### (Preparation of Semiconductor Photoresist Compositions)

### Examples 1 and 2 and Comparative Examples 1 to 3

Each of the compounds represented by Chemical Formulae 2 to 6 according to Synthesis Examples 1 to 5 was dissolved in an amount of 3 wt % in 4-methyl-2-pentanol and then, filtered with a 0.1 m PTFE syringe filter, preparing a photoresist composition. The photoresist compositions of Examples 1 and 2 were prepared using compounds represented by Chemical Formulae 2 and 3, respectively. The photoresist compositions of Comparative Examples 1 to 3 were prepared using compounds represented by Chemical Formulae 4 to 6, respectively.

### Evaluation 1: Evaluation of Etch Rate

An etch rate was measured by using a substrate on which a resist thin film was deposited and using Alliance equipment made by LAM. The measurement was performed under the following conditions.
Etching gas and flow rate: HBr, 500 seem
Chamber pressure and temperature: 90 mTorr, 20 °C
Etching time: 180 seconds
Evaluation 2: Evaluation of Contrast Performance

A substrate on which a resist thin film was deposited was exposed to an E-beam with an acceleration voltage of 100 kV, forming a 40 nm half-pitch nano wire. The irradiated substrate was exposed to 40 °C for 30 seconds, immersed in 2-heptanone contained in a Peri dish for 60 seconds, washed with the same solvent for 10 seconds, and finally baked at 150 °C, completing a patterned wafer. The patterned wafer was measured with respect to a thickness of each exposed portion to obtain a contrast curve, which was used to calculate contrast performance (γ(contrast)), and the results are shown in Table 1.
γ(contrast)=1/log(D₀/D₁₀₀)
D₁₀₀=an exposure dose at which 100% of PR remained
D₀=an exposure dose at which PR was completely removed

TABLE 1

| | Etch rate (Å/s) | γ (Contrast) |
|---|---|---|
| Example 1 | 14 | 6.5 |
| Example 2 | 16 | 6.4 |
| Comparative Example 1 | 23 | 6.8 |
| Comparative Example 2 | 22 | 6.3 |
| Comparative Example 3 | 21 | 3.9 |

Referring to Table 1, the photoresist compositions of Examples 1 and 2, compared with the photoresist compositions of Comparative Example 1 to 3, were confirmed to implement excellent metal-containing photoresist film removal ability, improved contrast performance, and excellent pattern characteristics.

By way of summation and review, extreme ultraviolet (EUV) lithography may be realized through development of compatible photoresists which can be performed at a spatial resolution of less than or equal to 16 nm. Currently, efforts to satisfy insufficient specifications of traditional chemically amplified (CA) photoresists such as a resolution, photospeed, and feature roughness (or also referred to as a line edge roughness or LER) for the next generation device are being made.

Intrinsic image blurring due to an acid catalyzed reaction in these polymer-type photoresists may limit a resolution in small feature sizes, which has been well known in electron beam (e-beam) lithography for a long time. The traditional chemically amplified (CA) photoresists are designed for high sensitivity, but since their typical elemental makeups may reduce light absorbance of the photoresists at a wavelength of 13.5 nm and thus may decrease their sensitivity, the traditional chemically amplified (CA) photoresists may partially have more difficulties under an EUV exposure.

In addition, the traditional CA photoresists may have difficulties in the small feature sizes due to roughness issues, and line edge roughness (LER) of the traditional CA photoresists may experimentally turn out to be increased, as photospeed is decreased partially due to an essence of acid catalyst processes. Accordingly, a novel high-performance photoresist is required in a semiconductor industry.

In order to overcome drawbacks of the traditional chemically amplified (CA) organic photosensitive compositions, an inorganic photosensitive composition has been researched. The inorganic photosensitive composition may be mainly used for negative tone patterning having resistance against removal by a developer composition due to chemical modification through nonchemical amplification mechanism. The inorganic composition may contain an inorganic element having a higher EUV absorption rate than hydrocarbon and thus may secure sensitivity through the nonchemical amplification mechanism and in addition, may be less sensitive to stochastic effect and thus may have low line edge roughness and the small number of defects.

Inorganic photoresists based on peroxopolyacids of tungsten mixed with tungsten, niobium, titanium, and/or tantalum have been reported as radiation sensitive materials for patterning.

These materials may be effective for patterning large pitches for bilayer configuration as far ultraviolet (deep UV), X-ray, and electron beam sources. More recently, when cationic hafnium metal oxide sulfate (HfSOx) materials along with a peroxo complexing agent have been used to image a 15 nm half-pitch (HP) through projection EUV exposure, impressive performance has been obtained.

This system may exhibit the highest performance of a non-CA photoresist and may have a practicable photospeed near to a requirement for an EUV photoresist. However, the hafnium metal oxide sulfate material having the peroxo complexing agent may have a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of 25 wt % and the like.

Recently, active research is being conducted into molecules including tin and having excellent absorption of extreme ultraviolet rays. As for an organotin polymer among them, alkyl ligands may be dissociated by light absorption or secondary electrons produced thereby, and may be crosslinked with adjacent chains through oxo bonds and thus enable the negative tone patterning which may not be removed by an organic developer. This organotin polymer may exhibit greatly improved sensitivity as well as maintains a resolution and line edge roughness, but the patterning characteristics may need to be additionally improved for commercial availability.

Some example embodiments may provide a semiconductor photoresist composition having improved contrast performance.

Some example embodiments may provide a method of forming patterns using the semiconductor photoresist composition.

By applying a semiconductor photoresist composition according to some example embodiments, an excellent photoresist pattern with improved contrast performance may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor photoresist composition, comprising:
an organometallic compound represented by Chemical Formula 1; and
a solvent:
Rₘ₁Sn(OR′)₄₋ₘ₁ [Chemical Formula 1]
wherein, in Chemical Formula 1,
R is a photosensitive reactive group containing at least one unsaturated bond,
R′ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, L^{a}-O—R^{a} (wherein L^{a} is a single bond or a substituted or unsubstituted C1 to C20 alkylene group and R^{a} is a substituted or unsubstituted C1 to C20 alkyl group, a substituted or unsubstituted C6 to C30 aryl group, or a substituted or unsubstituted C7 to C30 arylalkyl group), and
m1 is an integer of 1 to 3.

2. The semiconductor photoresist composition as claimed in claim 1, wherein:
R includes a substituted or unsubstituted C2 to C20 alkenyl group, a substituted or unsubstituted C6 to C30 aryl group, C(O)—R^{c} (wherein R^{c} is hydrogen, a substituted or unsubstituted C1 to C20 alkyl group, or a substituted or unsubstituted C6 to C30 aryl group), P(O)OR^{d}R^{e} (wherein R^{d} and R^{e} are each independently a substituted or unsubstituted C1 to C20 alkyl group or a substituted or unsubstituted C6 to C30 aryl group), P(O)OR^{f}OR^{g} (wherein R^{f} and R^{g} are each independently a substituted or unsubstituted C1 to C20 alkyl group or a substituted or unsubstituted C6 to C30 aryl group), S(O)R^{h} (wherein R^{h} is a substituted or unsubstituted C1 to C20 alkyl group or a substituted or unsubstituted C6 to C30 aryl group), or S(O)₂Rⁱ(wherein Rⁱ is a substituted or unsubstituted C1 to C20 alkyl group or a substituted or unsubstituted C6 to C30 aryl group); or
a group is linked to a substituent adjacent to R to form a C3 to C30 saturated alicyclic hydrocarbon group substituted with an unsaturated group, a substituted or unsubstituted C3 to C30 unsaturated alicyclic hydrocarbon group, or a substituted or unsubstituted C6 to C30 aromatic hydrocarbon group.

3. The semiconductor photoresist composition as claimed in claim 1, wherein:
Chemical Formula 1 is represented by Chemical Formula 1-1: 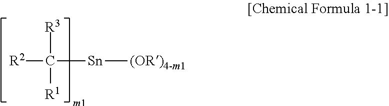
in Chemical Formula 1-1,
each R′ is independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, L^{a}-O—R^{a} (wherein L^{a} is a single bond or a substituted or unsubstituted C1 to C20 alkylene group and R^{a} is a substituted or unsubstituted C1 to C20 alkyl group, a substituted or unsubstituted C6 to C30 aryl group, or a substituted or unsubstituted C7 to C30 arylalkyl group),
R¹ to R³ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, C(O)—R^{c} (wherein R^{c} is a substituted or unsubstituted C1 to C20 alkyl group or a substituted or unsubstituted C6 to C30 aryl group), P(O)OR^{d}R^{e} (wherein R^{d} and R^{e} are each independently a substituted or unsubstituted C1 to C20 alkyl group or a substituted or unsubstituted C6 to C30 aryl group), P(O)OR^{f}OR^{g} (wherein R^{f} and R^{g} are each independently a substituted or unsubstituted C1 to C20 alkyl group or a substituted or unsubstituted C6 to C30 aryl group), S(O)R^{h} (wherein R^{h} is a substituted or unsubstituted C1 to C20 alkyl group or a substituted or unsubstituted C6 to C30 aryl group), or S(O)₂R′ (wherein Rⁱ is a substituted or unsubstituted C1 to C20 alkyl group or a substituted or unsubstituted C6 to C30 aryl group),
at least one of R¹ to R³ is a substituted or unsubstituted C2 to C20 alkenyl group, a substituted or unsubstituted C6 to C30 aryl group, C(O)—R^{c} (wherein R^{c} is hydrogen, a substituted or unsubstituted C1 to C20 alkyl group, or a substituted or unsubstituted C6 to C30 aryl group), P(O)OR^{d}R^{e} (wherein R^{d} and R^{e} are each independently a substituted or unsubstituted C1 to C20 alkyl group or a substituted or unsubstituted C6 to C30 aryl group), P(O)OR^{f}OR^{g} (wherein R^{f} and R^{g} are each independently a substituted or unsubstituted C1 to C20 alkyl group or a substituted or unsubstituted C6 to C30 aryl group), S(O)R^{h} (wherein R^{h} is a substituted or unsubstituted C1 to C20 alkyl group or a substituted or unsubstituted C6 to C30 aryl group), or S(O)₂Rⁱ(wherein Rⁱ is a substituted or unsubstituted C1 to C20 alkyl group or a substituted or unsubstituted C6 to C30 aryl group); or
adjacent groups among R¹ to R³ are linked to form a C3 to C30 saturated alicyclic hydrocarbon group substituted with an unsaturated group, a substituted or unsubstituted C3 to C30 unsaturated alicyclic hydrocarbon group, or a substituted or unsubstituted C6 to C30 aromatic hydrocarbon group, and
m1 is an integer of 1 to 3.

4. The semiconductor photoresist composition as claimed in claim 3, wherein:
at least one of R¹ to R³ is a substituted or unsubstituted phenyl group, a substituted or unsubstituted tolyl group, a substituted or unsubstituted xylene group, C(O)—R^{c} (wherein R^{c} is hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), C(R^{r})═C(R^{s})(R^{t}) (wherein R^{r}, R^{s}, and R^{t} are each independently hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), P(O)OR^{d}R^{e} (wherein R^{d} and R^{e} are each independently a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), P(O)OR^{f}OR^{g} (wherein R^{f} and R^{g} are each independently a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), S(O)R^{h} (wherein R^{h} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group), or S(O)₂Rⁱ (wherein Rⁱ is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted phenyl group, a substituted or unsubstituted tolyl group, or a substituted or unsubstituted xylene group); or
adjacent groups among R¹ to R³ are linked to form a cyclopentyl group substituted with an unsaturated group, a cyclohexyl group substituted with an unsaturated group, a cycloheptyl group substituted with an unsaturated group, a cyclooctyl group substituted with an unsaturated group, a cyclononyl group substituted with an unsaturated group, or a cyclodecyl group substituted with an unsaturated group.

5. The semiconductor photoresist composition as claimed in claim 3, wherein:
at least one of R¹ to R³ is a substituent of Group 1-1; or
adjacent groups among R¹ to R³ are linked to form one of the ring groups of Group 1-2: 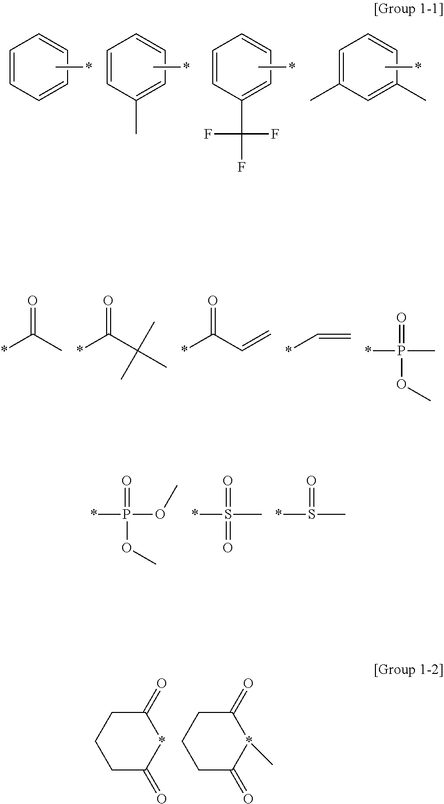
in Groups 1-1 and 1-2, * represents a carbon to which R¹ to R³ are linked.

6. The semiconductor photoresist composition as claimed in claim 1, wherein R′ is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, a substituted or unsubstituted methoxy group, a substituted or unsubstituted ethoxy group, a substituted or unsubstituted propoxy group, L^{a}-O—R^{a}(wherein L^{a} is a single bond, a substituted or unsubstituted methylene group, a substituted or unsubstituted ethylene group, or a substituted or unsubstituted propylene group, R^{a} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted phenyl group, a substituted or unsubstituted tolyl group, a substituted or unsubstituted xylene group, or a substituted or unsubstituted benzyl group), or a combination thereof.

7. The semiconductor photoresist composition as claimed in claim 1, wherein the organometallic compound is a compound of Group 2:

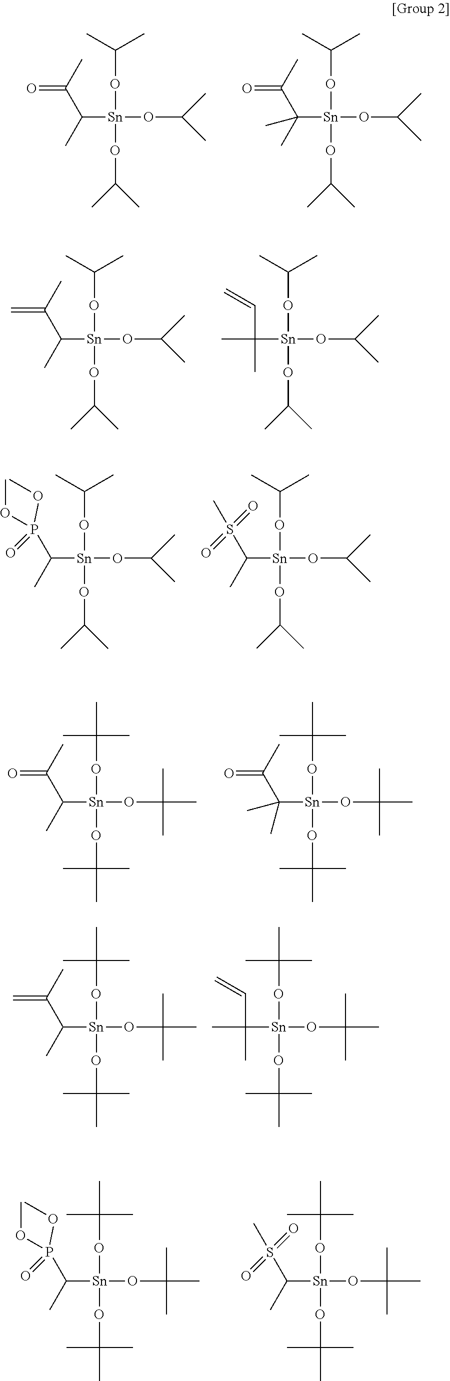

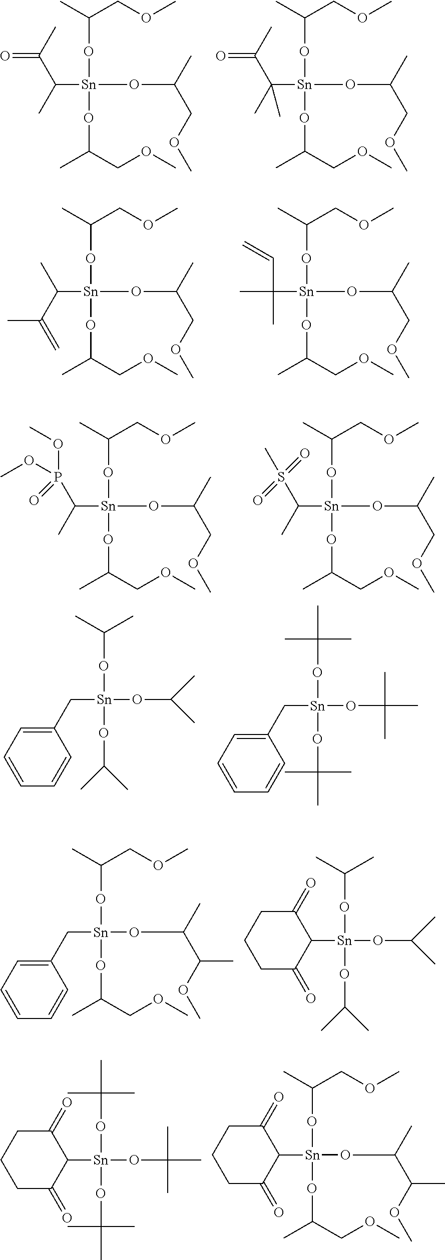

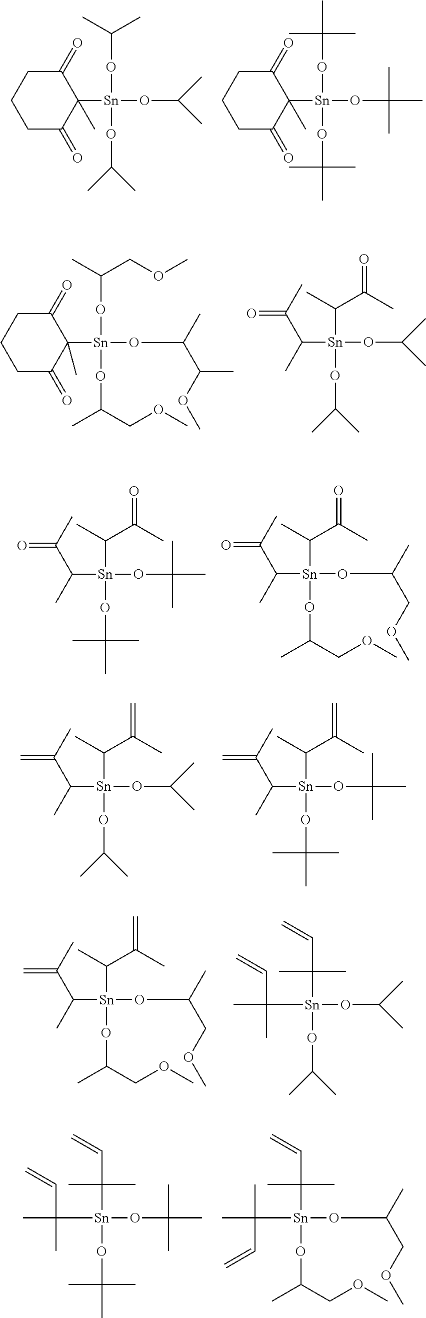

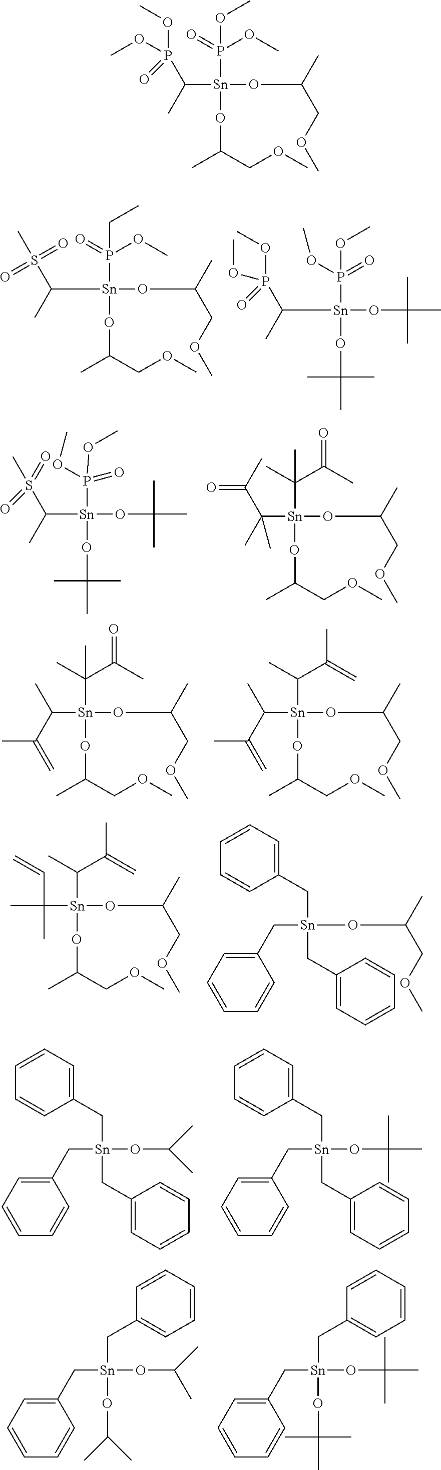

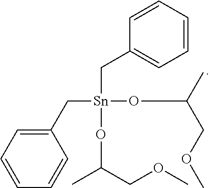 [SMILES: COCC(C)[O][Sn]([CH2]c1ccccc1)([CH2]c1ccccc1)[O]C(C)COC]

8. The semiconductor photoresist composition as claimed in claim 1, wherein the solvent includes an aromatic compound, an alcohol, an ester, a ketone, or a mixture thereof.

9. The semiconductor photoresist composition as claimed in claim 8, wherein the alcohol includes 4-methyl-2-pentenol, 4-methyl-2-propanol, 1-butanol, methanol, isopropyl alcohol, 1-propanol, or a mixture thereof.

10. The semiconductor photoresist composition as claimed in claim 1, wherein the organometallic compound is included in an amount of about 1 wt % to about 30 wt %, based on a total weight of the semiconductor photoresist composition.

11. The semiconductor photoresist composition as claimed in claim 1, wherein the semiconductor photoresist composition further includes a surfactant, a crosslinking agent, a leveling agent, or a combination thereof.

12. A method of forming patterns, the method comprising:
forming an etching-objective layer on a substrate;
coating the semiconductor photoresist composition as claimed in claim 1 on the etching-objective layer to form a photoresist film;
patterning the photoresist film to form a photoresist pattern; and
etching the etching-objective layer using the photoresist pattern as an etching mask.

13. The method of forming patterns as claimed in claim 12, wherein the photoresist pattern is formed using light having a wavelength of about 5 nm to about 150 nm.
